(19) United States
(12) Patent Application Publication
(10) Pub. No.: US 2019/0252565 A1
(43) Pub. Date: Aug. 15, 2019

(54) A MODULAR PHOTOVOLTAIC LOUVERED DEVICE

(71) Applicant: Mark LYONS, Sydney, New South Wales (AU)

(72) Inventor: Mark LYONS, Sydney, New South Wales (AU)

(21) Appl. No.: 16/333,411

(22) PCT Filed: Sep. 15, 2017
(86) PCT No.: PCT/AU2017/051003

§ 371 Date: Mar. 14, 2019

(30) Foreign Application Priority Data
Sep. 15, 2016 (AU) 2016903719
Oct. 28, 2016 (AU) 2016904423

(51) Int. Cl. H01L 31/054; E06B 7/084; H02S 20/25; H02S 50/00; H02S 20/26

(52) U.S. Cl. CPC H01L 31/054; E06B 7/084; H02S 20/26; H02S 50/00; H02S 20/25

(57) ABSTRACT

A modular photovoltaic louvered device having a rectangular framework; a plurality of photovoltaic louvre panels engaged in parallel within the framework, and electrical connector bearings interfacing each louvre panel and the framework, allowing the panels to rotate through a range and electrically connecting each panel to electronics within the framework. Each louvre panel includes: a transparent outer; a plurality of upper upwardly orientated photovoltaic cells operatively facing an upper surface; a plurality of lower downwardly orientated photovoltaic cells facing a lower surface; and a reflector located between the lower photovoltaic cells and the transparent outer. Each of the plurality of upper and lower photovoltaic cells occupy a surface area less than the photovoltaic louvre panels such that, light may pass through the transparent outer to a photovoltaic panel beneath such that the light captured by the device is increased by the lower photovoltaic cells being able to receive reflected light.

### FIELD OF THE INVENTION

This invention relates generally to a modular photovoltaic louvered device for buildings such as residential and commercial buildings such as apartments, offices and the like which may be installed within window openings, frames and the like.

### BACKGROUND OF THE INVENTION

Solar panels are utilised for harnessing solar energy for Electrical generation.

Certain installations comprise a plurality of solar panels in series feeding and electrical inverter. Such solar panels are generally planar and rooftop mounted for maximising exposure.

However, rooftop space is limited and a need exists for appropriate installations for the harnessing of solar energy from other available building areas such as building façades.

In this regard, façade mounted photovoltaic panels are known for use in capturing façade incident sunlight and building shading.

However, such façade mounted photovoltaic panels are costly and cumbersome requiring customised supportive rigging which is not feasible for all applications, especially residential application. Furthermore, the energy capture of such façade mounted photovoltaic panels is not particularly efficient.

The present invention seeks to provide a vertically mountable modular photovoltaic louvered device, which will overcome or substantially ameliorate at least some of the deficiencies of the prior art, or to at least provide an alternative.

It is to be understood that, if any prior art information is referred to herein, such reference does not constitute an admission that the information forms part of the common general knowledge in the art, in Australia or any other country.

### SUMMARY OF THE DISCLOSURE

There is provided herein a modular photovoltaic louvred device for solar powered electrical generation.

The device is integrally constructed in comprising a rectangular framework and a plurality of photovoltaic louvre panels rotatably engaged in parallel within the framework. The integral construction of the device allows modular installation thereof as a standalone unit negating the need for complex and costly façade supportive design and installation. In this manner, the device is able to be utilised substantially as is for accommodation within a suitably sized window or door void.

In this way, the present device may be utilised for replacement of existing window fittings or retrofitted to existing window frames and the like without extensive modification and associated cost. In embodiments, the device may easily also be wall mounted.

Embodiments of the device comprise electrical componentry for stand-alone utilisation wherein, in embodiments, stored electrical energy may be drawn directly from a power plug located on the device. Certain other embodiments comprise integral lighting provided for night time illumination from stored energy.

Embodiments of the device comprise a microcontroller for adjusting the angles of the photovoltaic louvre is for exercising energy capture, including in controlling the photovoltaic louvre panels independently.

In further embodiments, the photovoltaic louvre panels are configured for maximising energy capture efficiency given the particular stacked and overlapping configuration of the photovoltaic louvre panels.

Specifically, in these embodiments, the photovoltaic louvre panels comprise both upper and lower photovoltaic cells and wherein the panels are configured to increase energy captured by the lower photovoltaic cells.

In this way, the upper photovoltaic cells may capture directly incident light whereas the lower photovoltaic cells may capture reflected light, including light reflected from louvre panels beneath.

In embodiments, the photovoltaic louvre panels have a transparent outer and the interior photovoltaic cells may be spaced apart such that some of the directly incident light may pass therethrough to photovoltaic louvre panels underneath. We found that such an arrangement may increase efficiency in reducing heat build-up of the upper louvre panels in that heat is distributed more evenly across all of the louvre panels. The reduction in heat build-up increases the electrical energy conversion efficiency of the photovoltaic cells which would otherwise degrade from excessive heat build-up.

Furthermore, allowing light to pass to louvre panels beneath may further increase efficiency in more evenly distributing the light across all of the photovoltaic panels as opposed to saturating the upper louvre panels and shading the lower louvre panels.

In further embodiments, the undersurface of each louvre panel may comprise a reflector which, in embodiments, may take the form of a prismatic reflector.

The prismatic reflector may reflect, and, in embodiments scatter, light passing through the panel onto the undersurface photovoltaic cells, again increasing efficiency.

In embodiments, the prismatic reflector may provide substantial total internal reflection depending on the angle of incidence to maximise the light capture by both the upper and lower photovoltaic cells.

Our experimentation found that the lower photovoltaic cells could generate up to 40% of the electrical energy generated by the upper photovoltaic cells. Specifically, for a 1 m² device comprising 56 photovoltaic cells, we found that the upper photovoltaic cells could generate 196 W whereas the undersurface photovoltaic cells were able to generate 78 W providing a total power output of 274 W, being a greater power output achieved by the effective utilisation of both sides of the photovoltaic panels in the manner described herein.

As such, with the foregoing in mind, in accordance with one aspect, there is provided a modular photovoltaic louvered device comprising: a rectangular framework; a plurality of photovoltaic louvre panels engaged in parallel within the framework, each photovoltaic louvre defining an upper surface and a lower surface; electrical connector bearings interfacing each louvre panel and the framework allowing each louvre panel to rotate through an operative range and electrically connecting each louvre panel to electronics within the framework, wherein each louvre panel comprises: a transparent outer; a plurality of upper upwardly orientated photovoltaic cells operatively facing the upper surface; a plurality of lower downwardly orientated photovoltaic cells operatively facing the lower surface; and a reflector located between the lower photovoltaic cells and the transparent outer wherein: each of the plurality of upper and lower photovoltaic cells occupy a surface area less than that of each photovoltaic louvre panel.

As such, in use, an amount of light may pass through the transparent outer of each photovoltaic panel to a photovoltaic panel beneath such that the light captured by the device is increased by the lower photovoltaic cells being able to receive light reflected from a panel below and the reflector.

The reflective backing may be configured for scattering incident light.

The reflective backing comprises a prismatic reflector.

The device may further comprise a structural framework between the upper and lower photovoltaic cells.

The structural framework may be substantially transparent.

Each photovoltaic louvre panel may comprise a bi-convex cross-section.

The electronics may comprise a storage electronics comprising a plurality of electrical batteries.

The storage electronics may comprises a battery for each of the photovoltaic panels.

The device may further comprise power supply electronics comprising a power plug configured to supply power from the electrical batteries.

The device may further comprise an inverter operative between the electrical batteries and the power plug.

The device may further comprise lighting integrally formed within the framework and wherein, in use, the lighting may be configured for drawing electrical power from the electrical batteries.

The lighting may comprises an LED lighting strip array.

The lighting may be arranged at an upper surface of the framework.

The device may further comprise a light sensor operably coupled between the electoral batteries and the lighting, the light sensor configured for operating the lighting according to ambient light levels.

The device may further comprise a louvre adjustment actuator configured for adjusting the angle of the photovoltaic louvres and wherein the electronics further comprises a controller configured for controlling the louvre adjustment actuator for adjusting the angle of the photovoltaic louvres.

The controller may be configured for adjusting the angle of the photovoltaic louvres for maximising energy capture thereby.

The controller comprises a memory device storing seasonal almanac data and wherein the controller may be configured for controlling the angle of the photovoltaic louvres in accordance with the seasonal almanac data.

The electronics may further comprises a power sensor operably coupled to the controller configured for measuring the power output of the louvres and wherein the controller may be configured for adjusting the angle of the photovoltaic louvres to maximise the power output measured by the power sensor.

The controller may be configured for adjusting the photovoltaic louvres independently for maximising energy capture.

The controller may be configured for adjusting one of the photovoltaic louvres to reflect light onto lower photovoltaic cells of an above photovoltaic louvre panel.

Other aspects of the invention are also disclosed.

### BRIEF DESCRIPTION OF THE DRAWINGS

Notwithstanding any other forms which may fall within the scope of the present invention, preferred embodiments of the disclosure will now be described, by way of example only, with reference to the accompanying drawings in which:

FIG. 1 shows a perspective view of a modular photovoltaic louvred device in accordance with an embodiment;

FIGS. 2 and 3 show respectively orthogonal front views of the louvre panel of the device in accordance with an embodiment;

FIG. 4 shows a side cross-sectional view of the louvre panel in accordance with an embodiment;

FIG. 5 shows a perspective view of the device 1 comprising integral lighting and power outputs;

FIG. 6 shows a front elevation cross-sectional view of the device in accordance with an embodiment; and

FIGS. 7 and 8 illustrates the configuration of the louvre panels and the photovoltaic cells therein for increasing energy capture efficiency for the particular stacked and overlapping configuration of the panels.

### DESCRIPTION OF EMBODIMENTS

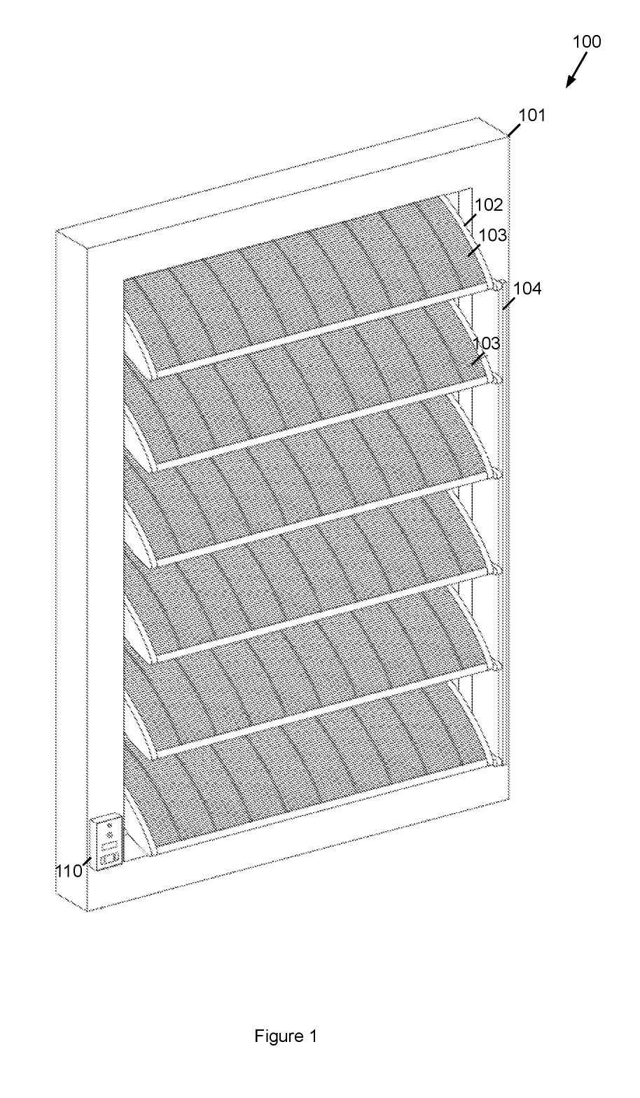

FIG. 1 shows a modular photovoltaic louvred device 100 comprising a rectangular framework 101 and a plurality of photovoltaic louvre panels 102 rotatably engaged within the framework 101. In a preferred embodiment, the framework 101 is substantially rectangular so as to allow for convenient recess within building façades such as window, door openings and the like.

Such a modular construction further assists in the retrofit of the device 100 wherein existing window or door furniture may be removed and easily replaced utilising an appropriately sized device 100.

Each louvre panel 102 comprises a plurality of photovoltaic cells 103.

The photovoltaic panels 102 are rotatably engaged within the framework 101 so as to be able to rotate between a substantially vertical orientation to close the device 101 and a substantially horizontal orientation to open the device 101.

A connector rod 104 may interface each of the louvre panels 102 for their moving in unison.

Electrical energy captured by the photovoltaic cells 103 may be stored by batteries within the framework 101 and accessed from an electrical power plug 110. The power plug 110 may deliver DC power and, in embodiment, the device 100 comprises an in-built inverter so as to deliver AC power. In this manner, the power plug 110 may comprise conventional mains power plug connectors, USB connector plugs or the like.

The framework 101 may be substantially hollow so as to accommodate the electrical componentry therein, including battery storage and the like.

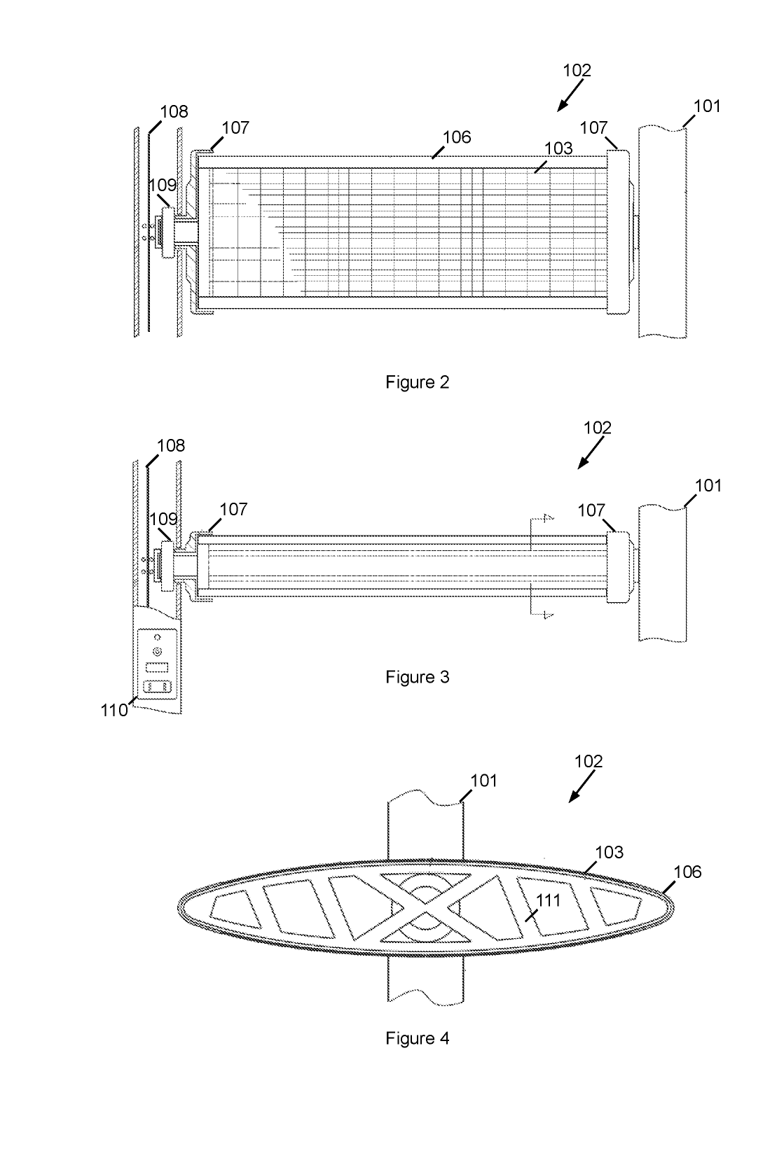

FIG. 2 shows a photovoltaic louvre panel 102 in further detail when engaged within the framework 101.

As can be seen, each louvre panel 102 is rotatably coupled by electrical connector bearing 109 within the framework 101. As such, each louvre panel 102 may rotate within the framework 101 while being able to provide electrical power via the bearings 109. In this regard, as can be seen, the interior of the framework 101 may comprise electrical cabling 108 to which the electrical connector bearings 109 may be electrically connected. As such, power generated by the photovoltaic louvre cells 102 may supply power by the electrical cabling 108 to the lexical componentry within the device 100.

Each louvre 102 may comprise a plurality of the photovoltaic cells 103 connected in series to the electrical connector bearing 107.

Each photovoltaic louvre panel 102 is substantially planar defining an upper and lower surface.

The photovoltaic cells 103 may be retained within each panel 102 utilising edge connector brackets 106 and lateral connector brackets 107.

FIG. 3 shows the louvre panel 102 having been rotated through 90° with respect to the orientation provided in FIG. 2.

Also shown in FIG. 3 is the electrical power outlet 110 which, as alluded to above, may supply DC and/or AC power. Additional status indicators may be provided at the plug 110, such as battery state status indicators and the like.

FIG. 4 shows a cross-sectional view of the louvre panel 102 angled at 90° with respect to the framework 101.

As can be seen, in this embodiment, the panel 102 is bi-convex. A structural framework 111 may be provided within the interior of the panel 102. The structural framework 111 may be transparent in embodiments or spaced apart so as to allow light to pass through the louvre panel 102 in embodiments described below.

The photovoltaic cells 103 may be located within each panel 102 at the surfaces thereof, such as the upper and lower surfaces in the manner described herein. In this regard, the exterior of the panel 102 to be transparent so as to allow light to reach the photovoltaic cells 103.

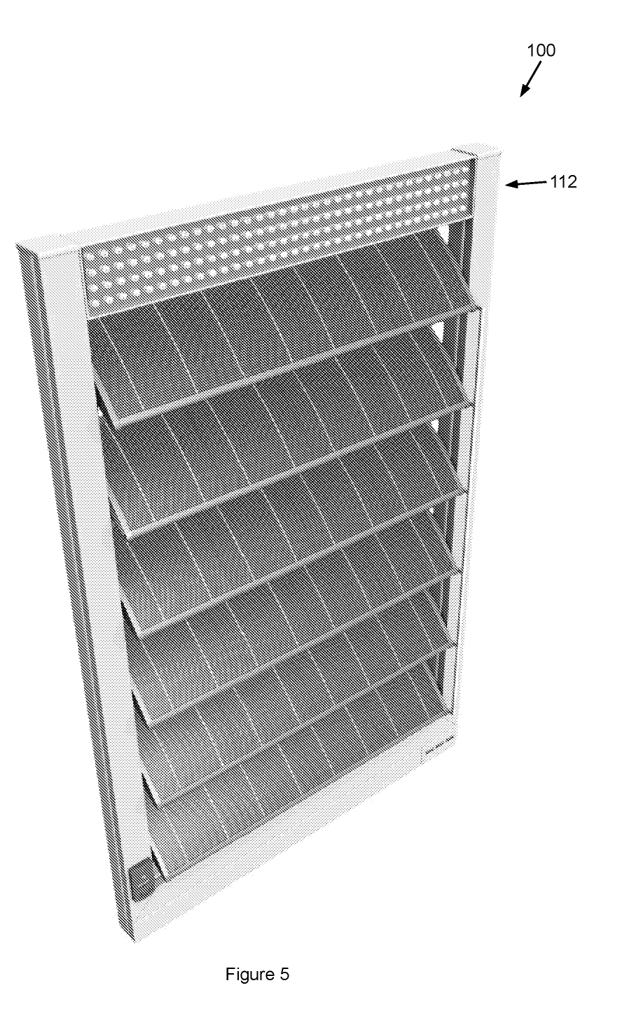

FIG. 5 shows a top perspective view of the device 100 in accordance with an embodiment wherein as can be seen, the device 100 comprises lighting 112, which takes the form of an LED lighting array strip in the embodiment shown. In this manner, and as alluded to above, the device 100 may generate and store electrical energy during the day for powering the lighting 112 at night. The electrical componentry of the device 100 may comprise light sensors for operating the lighting 112 when required. Furthermore, in embodiments, timers may be provided so as to extinguish the lighting at a certain time at night when no longer required. Furthermore, electrical control circuitry may control the operation of the lighting 112 depending on the charge state of the electrical batteries within the device 100. In further embodiments, the operation of the lighting 112 may be user controlled.

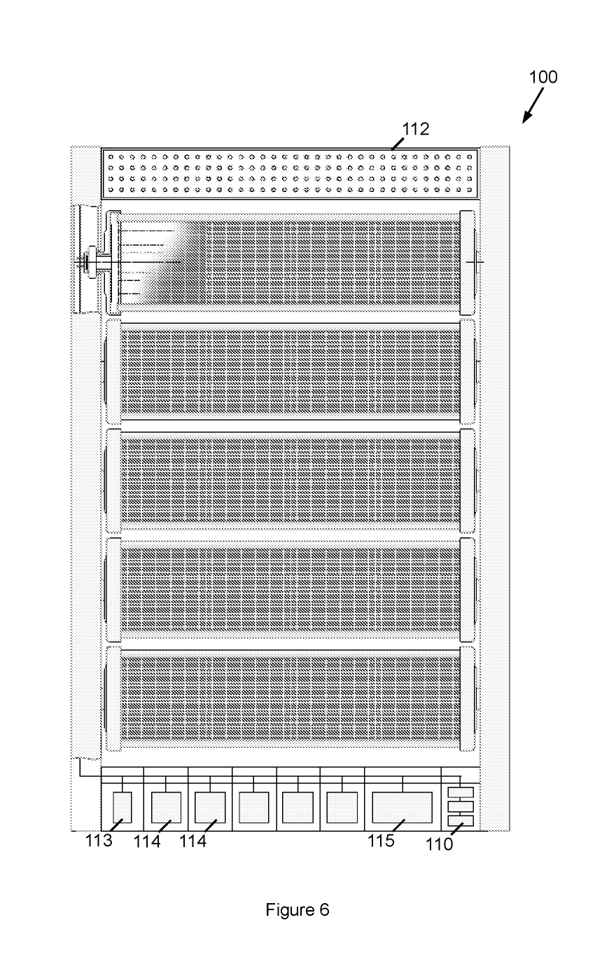

FIG. 6 shows a front elevation cross-sectional view of the device 100. As can be seen, in the embodiments provided in FIG. 6, the device 100 comprises the aforedescribed LED lighting strip array 112.

As also alluded to above, the interior of the framework 101 may be hollow so as to allow for the accommodation of various electrical componentry, including that which is shown in FIG. 6.

In a preferred embodiment, the electrical componentry is located within the lower portion of the framework 101 which may be accessed by a removable panel if required.

In the embodiments shown, the electrical componentry comprises a plurality of batteries 114 for electrical storage. As alluded to above, the batteries 114 are electrically connected to each photovoltaic panel 102 and the photovoltaic cells 103 therein by way of the electrical connector bearings 109 so as to be charged thereby.

In embodiments shown, a separate battery 114 may be provided for each panel 102 further increasing the operational efficiency of the device 100.

The electrical componentry may further comprise a microcontroller 115 for controlling various operational aspects of the device 100.

For example, the microcontroller 115 may control the charging and discharging of the batteries 114, the monitoring of the charge state thereof and the like.

In embodiments, the angle or orientation of the panels 102 may be user configured. However, in embodiments, the device 100 may comprise an actuator (not shown) for setting the angle of the panels 102.

In embodiments, the angle adjustment actuator may be controlled by the microcontroller 115 for controlling the angle of the panels 102 to optimise the operation thereof, including for energy capture maximisation. For example, in accordance with seasonal almanac data or by monitoring the electrical generation of each panel 102, the microcontroller 115 may be configured for adjusting the angles of the panels 102 to maximise energy capture.

In embodiments, the microcontroller 115 may adjust each panel 102 independently to maximise energy capture wherein, for example, the microcontroller 115 may adjust one of the panels 102 to reflect light onto the undersurface of the panel 102 above if such were to maximise energy capture.

The microcontroller 115 may further control the operation of the louvre panels 102 in accordance with the operational parameters including environmental parameters wherein, for example, on a hot day, which may be ascertained utilising a thermocouple device (not shown), the microcontroller 115 may open the louvre panels 102 to call the interior of the building.

The electrical componentry may further comprise the aforedescribed electrical inverter 113 for supplying various electrical power outlets 110.

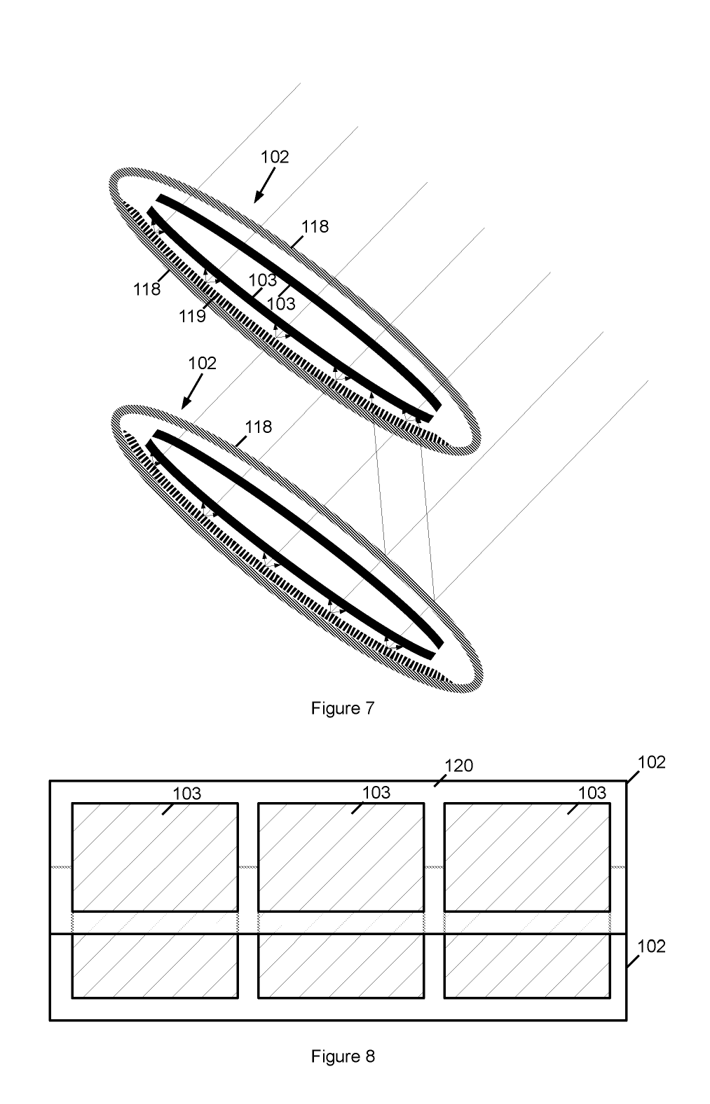

FIGS. 7 and 8 show an embodiment of the louvre panels 102 to maximise energy capture given the particular stacked and overlapping configuration of the louvre panels 102 being distinct from conventional laid-out-flat and spaced apart rooftop mounted solar panels.

As is shown in FIG. 7, each louvre panel 102 may comprise a transparent outer 118, thereby defining an upper surface and a lower surface.

Furthermore, each panel 102 may comprise corresponding upper and lower photovoltaic panels 103 therein respectively facing the upper and lower surfaces of the panel 102.

As such, light passing through the upper surface of the outer transparent covering 118 strikes the upper photovoltaic cell 103 and similarly, light passing through the lower surface of the outer transparent covering 118 strikes the lower photovoltaic cell 103.

As such, the lower photovoltaic cells 103 may capture reflected light. Specifically, as is illustrated in FIG. 7, light may be reflected from a louvre panel 102 beneath onto the lower photovoltaic cell 103. Furthermore, even when the device 100 is closed, the lower photovoltaic cells 103 may capture light emanating from within the interior of the building.

In embodiments, as is shown in FIG. 8, the photovoltaic cells 103 may be spaced apart so as to provide a transparent surrounding 120 through which light may pass through to the lower photovoltaic cell 103 or the photovoltaic louvres 102 beneath.

In an embodiment, an interior reflective backing 119 may be provided within each photovoltaic louvre panel 102.

In embodiments, the reflective backing 119 takes the form of a prismatic reflector configured for reflecting irrespective of the angle of the photovoltaic louvre panel 102.

As such, as can be seen, light passing through the transparent surrounding 120 may strike the reflective backing 119 so as to be reflected onto the lower photovoltaic cell 103.

In embodiments, the reflective backing 119 may be configured to scatter the light onto the lower photovoltaic cells 103 as shown.

As can be also seen from FIG. 8, a certain amount of light may pass entirely through each photovoltaic panel 102 to strike the photovoltaic panel 102 beneath.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. A modular photovoltaic louvered device comprising: a rectangular framework;
a plurality of photovoltaic louvre panels engaged in parallel within the framework, each photovoltaic louvre defining an upper surface and a lower surface;
electrical connector bearings interfacing each louvre panel and the framework allowing each louvre panel to rotate through an operative range and electrically connecting each louvre panel to electronics within the framework, wherein each louvre panel comprises:
a transparent outer;
a plurality of upper upwardly orientated photovoltaic cells operatively facing the upper surface;
a plurality of lower downwardly orientated photovoltaic cells operatively facing the lower surface; and
a reflector located between the lower photovoltaic cells and the transparent outer wherein:
each of the plurality of upper and lower photovoltaic cells occupy a surface area less than that of each photovoltaic louvre panel such that, in use, an amount of light may pass through the transparent outer of each photovoltaic panel to a photovoltaic panel beneath such that the light captured by the device is increased by the lower photovoltaic cells being able to receive light reflected from a panel below and the reflector.

2. The device as claimed in claim 1, wherein the reflective backing is configured for scattering incident light.

3. The device as claimed in claim 1, wherein the reflective backing comprises a prismatic reflector.

4. The device as claimed in claim 1, further comprising a structural framework between the upper and lower photovoltaic cells.

5. A The device as claimed in claim 4, wherein the structural framework is substantially transparent.

6. The device as claimed in claim 1, wherein each photovoltaic louvre panel comprises a bi-convex cross-section.

7. The device as claimed in claim 1, wherein the electronics comprise a storage electronics comprising a plurality of electrical batteries.

8. The device as claimed in claim 7, wherein the storage electronics comprises a battery for each of the photovoltaic panels.

9. The device as claimed in claim 7, further comprising power supply electronics comprising a power plug configured to supply power from the electrical batteries.

10. The device as claimed in claim 9, further comprising an inverter operative between the electrical batteries and the power plug.

11. The device as claimed in claim 7, further comprising lighting integrally formed within the framework and wherein, in use, the lighting is configured for drawing electrical power from the electrical batteries.

12. The device as claimed in claim 11, wherein the lighting comprises an LED lighting strip array.

13. The device as claimed in claim 11, wherein the lighting is arranged at an upper surface of the framework.

14. The device as claimed in claim 11, further comprising a light sensor operably coupled between the electoral batteries and the lighting, the light sensor configured for operating the lighting according to ambient light levels.

15. The device as claimed in claim 1, further comprising a louvre adjustment actuator configured for adjusting the angle of the photovoltaic louvres and wherein the electronics further comprises a controller configured for controlling the louvre adjustment actuator for adjusting the angle of the photovoltaic louvres.

16. The device as claimed in claim 15, wherein the controller is configured for adjusting the angle of the photovoltaic louvres for maximising energy capture thereby.

17. The device as claimed in claim 16, wherein the controller comprises a memory device storing seasonal almanac data and wherein the controller is configured for controlling the angle of the photovoltaic louvres in accordance with the seasonal almanac data.

18. The device as claimed in claim 16, wherein the electronics further comprises a power sensor operably coupled to the controller configured for measuring the power output of the louvres and wherein the controller is configured for adjusting the angle of the photovoltaic louvres to maximise the power output measured by the power sensor.

19. The device as claimed in claim 16, wherein the controller is configured for adjusting the photovoltaic louvres independently for maximising energy capture.

20. The device as claimed in claim 19, wherein the controller is configured for adjusting one of the photovoltaic louvres to reflect light onto lower photovoltaic cells of an above photovoltaic louvre panel.
